(19) United States
(12) Patent Application Publication
(10) Pub. No.: US 2017/0345954 A1
(43) Pub. Date: Nov. 30, 2017

(54) COLORED PHOTOVOLTAIC MODULES

(71) Applicant: SolarCity Corporation, San Mateo, CA (US)

(72) Inventors: Yangsen Kang, Santa Clara, CA (US); Zhigang Xie, San Jose, CA (US); Jianhua Hu, Palo Alto, CA (US); Zheng Xu, Pleasanton, CA (US)

(73) Assignee: SolarCity Corporation, San Mateo, CA (US)

(21) Appl. No.: 15/294,042

(22) Filed: Oct. 14, 2016

Related U.S. Application Data
(60) Provisional application No. 62/343,659, filed on May 31, 2016.

(51) Int. Cl. H01L 31/0236; H01L 31/056; H01L 31/049; H01L 31/18; H01L 31/0216

(52) U.S. Cl. CPC H01L 31/02366; H01L 31/18; H01L 31/02168; H01L 31/049; H01L 31/056; H01L 31/02162

(57) ABSTRACT

A low-reflection-loss low-angle-sensitive colored photovoltaic (PV) module is described. This colored PV module includes a transparent substrate; an array of solar cells encapsulated between a top encapsulation sheet and a bottom encapsulation sheet; and a color filter structure embedded between the top encapsulation sheet and the transparent substrate and configured to cause wavelength-selective reflections of incident light received by the colored PV module. Moreover, the transparent substrate includes a flat front surface configured to receive the incident light and a texture back surface configured with an array of features. The color filter structure is formed on the textured back surface of the transparent substrate to create a textured interface between the textured back surface and the color filter structure.

### RELATED APPLICATION

This application claims the benefit of U.S. Provisional Application No. 62/343,659, Attorney Docket Number P301-1PUS, entitled “MULTI-LAYER OPTICAL COATINGS ON TEXTURED GLASS AND ITS APPLICATION OF COLORED PV MODULES,” by inventors Yangsen Kang, Zhigang Xie, Jianhua Hu, and Zheng Xu, filed May 31, 2016, the disclosure of which is incorporated by reference herein.

### BACKGROUND

### Field

This disclosure is generally related to the designs of photovoltaic (or “PV”) modules. More specifically, this disclosure is related to designs and fabrication of low-reflection-loss, low-angle-sensitive colored PV modules.

### Related Art

Crystalline-silicon based solar cells have been shown to have superb energy conversion efficiency. While device design and fabrication techniques continue to mature, and with the price of crystalline silicon becoming progressively lower, solar panels are being offered at historical low prices. In addition, with newly available financing plans and government subsidies, customers, both residential and commercial, now have unprecedented incentives to install solar panels. As a result, the solar market is expected to experience double-digit growth for many years to come.

Commercial solar panels are constructed by assembling arrays of photovoltaic (or “PV”) modules, wherein each PV module is typically composed of a two-dimensional array (e.g., 6×10) of solar cells. The color of PV modules is usually determined by the natural color of the solar cells embedded in the PV modules, which is generally blue, dark-blue or black. However, it is often desirable for customers to be able to select the color appearance of the PV modules, for example, so that they match the color of the buildings which they are incorporated into.

There are a number of existing techniques for providing colored PV modules. One of them involves applying tinted glass and/or colored encapsulation sheets in PV modules. However, these extra structures can have a strong absorption of the sunlight thereby causing significant power loss to the PV modules. Moreover, the color appearance provided by these additional structures tends to degrade over time.

Another coloration technique involves applying a color filter over the PV modules or over the solar cells. In this technique, multilayer dielectric films are deposited on the PV modules or the solar cells to modulate color appearance. The design of these films is often complex and therefore this technique may not be cost-effective for mass production. Furthermore, the color appearance achieved by the coatings over the PV modules or the solar cells is typically angle-sensitive and can also degrade over time under environmental stresses (such as marine weather). Moreover, applying extra coatings over the PV modules or the solar cells can introduce additional integration complexity, higher automation cost, and plasma damage to the solar cells.

### SUMMARY

One embodiment described herein provides a colored photovoltaic (PV) module. This colored PV module includes a transparent substrate; an array of solar cells encapsulated between a top encapsulation sheet and a bottom encapsulation sheet; and a color filter structure embedded between the top encapsulation sheet and the transparent substrate and configured to cause wavelength-selective reflections of incident light received by the colored PV module. Moreover, the transparent substrate includes a flat front surface configured to receive the incident light and a texture back surface configured with an array of features. The color filter structure is formed on the textured back surface of the transparent substrate to create a textured interface between the textured back surface and the color filter structure.

In a variation on this embodiment, the textured back surface is configured to cause majority of the incident light received by the PV module to reflect at least twice on the textured interface so that the wavelength-selective reflections comprise primarily light reflected two or more times on the textured interface.

In a variation on this embodiment, the textured back surface can be tuned to control an amount of reflection loss caused by the textured interface by increasing or decreasing an amount of multiple reflections of the incident light on the textured interface, wherein increasing the amount of multiple reflections decreases the amount of reflection loss.

In a variation on this embodiment, the color filter structure facilitates a desired color appearance of the PV module when viewed above the front surface of the transparent substrate, and the desired color appearance is not substantially angle-sensitive.

In a variation on this embodiment, each of the features in the textured back surface includes at least one angled sidewall, which forms a texture angle of the textured back surface with the plane of the front surface of the transparent substrate.

In a variation on this embodiment, the texture angle of the textured back surface can be tuned to cause majority of the incident light received by the PV module to reflect at least twice on the textured interface.

In a variation on this embodiment, the texture angle of the textured back surface can be configured to control an amount of reflection loss caused by the textured interface.

In a variation on this embodiment, the texture angle of the textured back surface is set to be substantially equal to or greater than a threshold angle which causes majority of the incident light received by the PV module to reflect at least twice on the textured interface. Consequently, the wavelength-selective reflections from the textured interface comprise primarily light reflected two or more times on the textured interface. In some embodiments, this threshold angle is approximately 45°.

In a variation on this embodiment, the carrier includes an interlocking mechanism on at least one edge, thereby facilitating interlocking with a second carrier to form a wafer carrier system.

In a variation on this embodiment, the wavelength-selective reflections caused by the color filter structure configured with the set texture angle generate a desired color appearance of the PV module when viewed above the front surface of the transparent substrate, and wherein the desired color appearance is not substantially angle-sensitive.

In a variation on this embodiment, the array of features can be in either an upright configuration or an inverted configuration. In some embodiments, the array of features can be an array of grooves, an array of cones, an array of triangular pyramids, an array of square pyramids, or an array of hexagonal pyramids.

In a variation on this embodiment, each of the features has both a flat top surface and a tapered sidewall.

In a variation on this embodiment, each of the features has a feature size ranging from 10 μm to 5 mm.

In a variation on this embodiment, the array of features is arranged in a repeating pattern which can include a square lattice, a rectangular lattice, or centered rectangular lattice.

In a variation on this embodiment, the array of features is distributed randomly across the back surface of the transparent substrate.

In a variation on this embodiment, the color filter structure includes multiple layers of optical coatings. In some embodiments, the multiple layers of optical coatings include alternating high refraction index and low refraction index optical coatings. For example, the multiple layers of optical coatings include at least a three-layer stack of TiO₂/SiO₂/TiO₂.

In a variation on this embodiment, the color filter structure is fabricated on the textured back surface of the transparent substrate by depositing the multiple layers of optical coatings on the textured back surface.

In a variation on this embodiment, the colored PV module further includes an antireflective coating (ARC) deposited on the front surface of the transparent substrate and configured to reduce unwanted reflections and a backside cover attached to the bottom encapsulation sheet.

In a variation on this embodiment, the transparent substrate is a glass substrate.

In another aspect of this disclosure, a top glass structure for a colored PV module is disclosed. This top glass structure includes a transparent substrate which has a flat front surface configured to receive incident light and a textured back surface configured with an array of 3D shapes. The top glass structure also includes a color filter structure formed on the textured back surface of the transparent substrate to create a textured interface between the textured back surface and the color filter structure. This color filter structure is configured to cause wavelength-selective reflections of the incident light.

In yet another aspect, a process for fabricating a colored PV module is disclosed. This processing includes: preparing a transparent substrate that includes a flat front surface configured to receive incident light and a textured back surface configured with an array of 3D shapes; forming a color filter structure on the textured back surface of the transparent substrate to create a textured interface between the textured back surface and the color filter structure; and assembling the transparent substrate and the color filter structure with an array of solar cells encapsulated between a top encapsulation sheet and a bottom encapsulation sheet. In various embodiments, the color filter structure is configured to cause wavelength-selective reflections of the incident light.

### BRIEF DESCRIPTION OF THE FIGURES

The patent or application file contains at least one drawing executed in color. Copies of this patent or patent application publication with color drawing(s) will be provided by the Office upon request and payment of the necessary fee.

FIG. 1 presents a diagram illustrating a cross-sectional view of an exemplary PV module in accordance with one embodiment described herein.

FIG. 2 presents a diagram illustrating a cross-sectional view of an exemplary PV module including an embedded texture structure in accordance with one embodiment described herein.

FIG. 3 shows various examples of the textured back surface of the disclosed textured substrate in the disclosed PV module in accordance with one embodiment described herein.

FIG. 4 shows various examples of the 3D feature shapes which can be used to form the textured back surface of the disclosed textured substrate in the disclosed PV module in accordance with one embodiment described herein.

FIG. 5A presents a diagram illustrating a cross-sectional view of an exemplary flat interface formed between a flat back surface of a transparent substrate and a flat color filter such as the one shown in the PV module of FIG. 1.

FIG. 5B presents a diagram illustrating a cross-sectional view of an exemplary textured interface formed between a textured back surface of a transparent substrate and a color filter deposited on the textured transparent substrate in accordance with one embodiment described herein.

FIG. 5C illustrates the effect of using a greater texture angle within an exemplary textured interface on the reduction of reflection losses in accordance with one embodiment described herein.

FIG. 5D presents a diagram illustrating a cross-sectional view of an exemplary textured interface formed between a textured back surface of a substrate and a color filter in a PV module and having a texture angle set at a value to cause majority of the incident light to experience multiple reflections in accordance with one embodiment described herein.

FIG. 6A presents a diagram illustrating a cross-sectional view of an exemplary structure for the color filter described in FIG. 2 in accordance with one embodiment described herein.

FIG. 6B presents a diagram illustrating a cross-sectional view of another exemplary structure for the color filter described in FIG. 2 in accordance with one embodiment described herein.

FIG. 7 presents a plot showing simulated reflection spectra of different designs of the textured glass substrate in combination with a three-layer color filter in exemplary PV modules in accordance with one embodiment described herein.

FIG. 8 presents a plot showing simulated reflection spectra of a three-layer color filter deposited on a 55° textured glass substrate when measured at different viewing angles in accordance with one embodiment described herein.

In the figures, like reference numerals refer to the same figure elements.

### DETAILED DESCRIPTION

The following description is presented to enable any person skilled in the art to make and use the embodiments, and is provided in the context of a particular application and its requirements. Various modifications to the disclosed embodiments will be readily apparent to those skilled in the art, and the general principles defined herein may be applied to other embodiments and applications without departing from the spirit and scope of the present disclosure. Thus, the present invention is not limited to the embodiments shown, but is to be accorded the widest scope consistent with the principles and features disclosed herein.

### Overview

Various embodiments disclosed herein provide solutions to manufacturing photovoltaic (PV) modules with customized color appearances without introducing problems associated with traditional colored PV modules such as high reflection loss, color degradation, high integration complexity, high cost, and plasma damage to the solar cells. In some embodiments, the desired color appearance of a PV module can be achieved by forming a color filter in the form of optical coatings on the inner surface of a transparent substrate of the PV module. However, these additional optical coatings could introduce additional reflection losses within the PV module.

To reduce the reflection losses caused by the embedded color filter, some embodiments described herein provide various examples of a transparent substrate having a textured back surface instead of a flat back surface and forming the color filter on this textured back surface to create a textured interface between the textured back surface of the transparent substrate and the color filter structure. Moreover, the textured back surface of the transparent substrate can be configured to cause majority of the incident light received by the PV module to reflect at least twice on the textured interface so that the wavelength-selective reflections caused by the color filter include primarily light reflected two or more times on the textured interface. This textured back surface can also be tuned to control the amount of reflection loss caused by the textured interface by increasing or decreasing the amount of multiple reflections of the incident light on the textured interface.

One of the drawbacks associated with conventional colored PV modules is that the resulting color appearance is highly angle-sensitive. This unwanted effect is largely the result of the fact that a larger viewing angle receives reflections of light having larger incident angles, while a smaller viewing angle receives reflections of light having smaller incident angles.

Using the disclosed colored PV modules composed of multilayer color filters formed on the textured back surfaces of the transparent substrates, the angle sensitivity of the resulting color appearances can be significantly reduced. This reduction of angle sensitivity is at least partly due to the fact that majority of the incident light experiences multiple reflections at the textured interface (when the texture angle is properly selected). As such, at a given viewing angle, the received reflections at that angle is no longer primarily coming from the light having incident angles at or near that viewing angle. Instead, the received reflections are a combination of reflected light corresponding to incident light at different incident angles. Hence, the disclosed colored PV modules generate desired color appearances that are not angle-sensitive.

### Detailed Embodiments and Examples

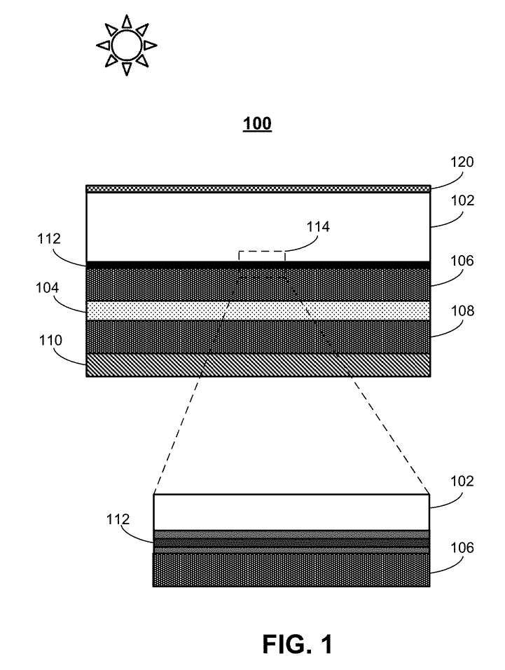

FIG. 1 presents a diagram illustrating a cross-sectional view of exemplary PV module 100 in accordance with one embodiment described herein. As can be seen in FIG. 1, PV module 100 includes transparent substrate 102, which is typically made of glass, array of solar cells 104, and top encapsulation sheet 106 and bottom encapsulation sheet 108, which are positioned on the front side and the back side of solar cells 104 to encapsulate solar cells 104. In some embodiments, encapsulation sheets 106 and 108 are made of a transparent material such as polyvinyl butyral (PVB), thermoplastic olefin (TPO), or ethylene vinyl acetate (EVA). However, encapsulation sheets 106 and 108 can be made of other conventional or newly-developed encapsulation materials. PV module 100 additionally includes a back-side cover layer 110 positioned on the back side of PV module 100 opposite to substrate 102.

Note that when PV module 100 is used to convert light to an electrical current, PV module 100 is positioned such that transparent substrate 102 is facing toward a light source to receive incident light. We refer to the first surface of transparent substrate 102 on the outside of the PV module, facing the light source and receiving the incident light as the “top” or “front” or “outer” surface of transparent substrate 102, while the second surface of transparent substrate 102 facing solar cells 104 as the “bottom” or “back” or “inner” surface of transparent substrate 102. In the embodiment shown, both the front/top/outer surface and back/bottom/inner surface of transparent substrate 102 are flat surfaces. In various embodiments, PV module 100 can also include an anti-reflective coating (ARC) 120 deposited on the front surface of substrate 102 to reduce unwanted reflection. Note that while not shown, PV module 100 can include additional structures such as electrodes.

PV module 100 can also include a color filter 112 embedded between top encapsulation sheet 106 and transparent substrate 102 and configured to achieve a desired color appearance by causing wavelength-selective reflections of the incident light. In some embodiments, color filter 112 can include one or more layers of optical coatings. A zoom-in view of a region 114 of transparent substrate 102 and color filter 112 shows that color filter 112 can further include one or more thin film layers which also have flat surfaces because the back surface of transparent substrate 102 is flat. However, the flat surfaces of color filter 112 introduce additional reflection interfaces into PV module 100, which can generate reflection due to interferometric effects and lead to a great deal of (e.g., >20%) loss of incident light power. To reduce this reflection loss caused by the embedded color filter 112, some embodiments described herein provide a transparent substrate having a textured back surface instead of a flat back surface, and the color filter can be formed directly over this textured back surface to create a textured interface between the textured back surface of the transparent substrate and the color filter structure.

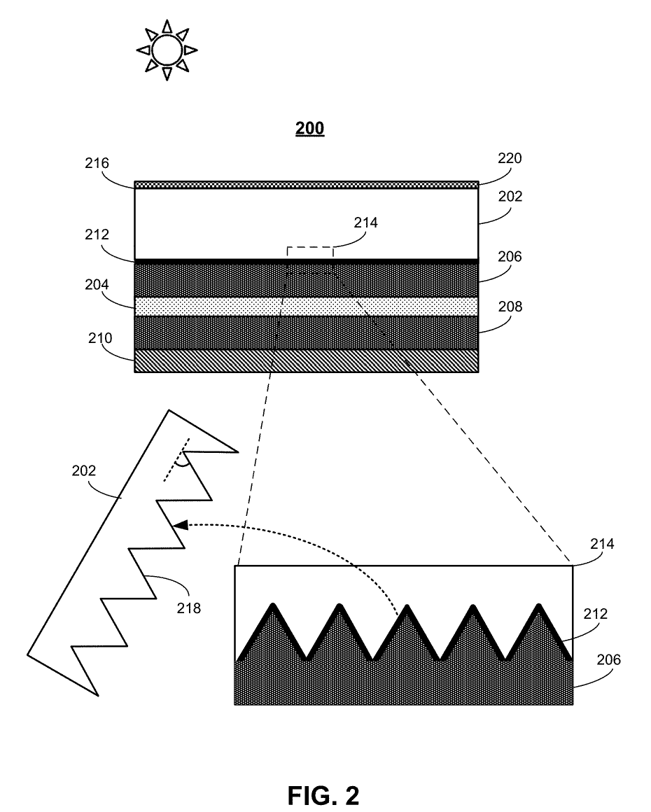

FIG. 2 presents a diagram illustrating a cross-sectional view of an exemplary PV module 200 including an embedded texture structure in accordance with one embodiment described herein. As can be seen in FIG. 2, PV module 200 can have many similar components as in PV module 100, including transparent substrate 202, such as a glass substrate, array of solar cells 204, transparent top encapsulation sheet 206, transparent bottom encapsulation sheet 208, backside cover layer 210, and ARC coating 220. While not shown, PV module 200 can also include electrodes.

PV module 200 can additionally include color filter 212 embedded between top encapsulation sheet 206 and transparent substrate 202 and configured to achieve a desired color appearance by causing wavelength-selective reflections of the incident light. However, a zoom-in view of a region 214 of transparent substrate 202 and color filter 212 shows some of the significant differences between PV module 100 and PV module 200.

As shown in both the main diagram and within window 214 in FIG. 2, transparent substrate 202 can have a flat top/front surface 216 which is configured to receive incident light, and textured back surface 218 facing the solar cells 204 in PV module 200. To provide a better view of the textured back surface 218, substrate 202 inside window 214 is shown in a separated diagram to the left of window 214. The textured back surface 218 can include an array of features which can be characterized by a certain texture angle. Color filter 212, which is shown as the zigzagging structure between textured back surface 218 and top encapsulation sheet 206, can follow the features of the textured back surface 218 and, as a result, obtain both textured front surface (i.e., the one facing back surface 218) and textured back surface (i.e., the one facing top encapsulation sheet 206) instead of flat surfaces as in color filter 112. Hence, a textured interface can be created between the textured back surface 218 of transparent substrate 202 and a textured front surface of color filter 212.

Note that the particular cross-sectional profile of the textured back surface 218 shown in FIG. 2 is merely used as an example, while in other embodiments the cross-section of the textured back surface of substrate 202 can have many other profiles different from the particular one shown in FIG. 2.

Similarly to color filter 112, textured color filter 212 can also be configured to cause wavelength-selective reflections of the incident light in order to achieve a desired color appearance for PV module 200. In some embodiments, color filter 212 can include multiple thin film layers which are formed directly over the textured back surface 218 using one of the thin film deposition techniques, such as chemical or physical vapor deposition (CVD or PVD), or sputtering. The textured substrate 202 and color filter 212 can then be integrated with the other portions of PV module 200.

In some embodiments, the textured back surface 218 of the disclosed textured substrate 202 can include an array of three-directional (3D) features, wherein each of the 3D features can have a feature size ranging from 10 μm to 5 mm. This array of 3D features is also referred to as a “textured structure” below. In various embodiments, the 3D features can be configured either upright or inverted. The shape of the 3D features forming the textured structure can include, but are not limited to, grooves, cones, pyramids with triangle, square or hexagonal bases. In some embodiments, textured back surface 218 can be manufactured using a texture roller process and/or a chemical etching processes following by a tempering process.

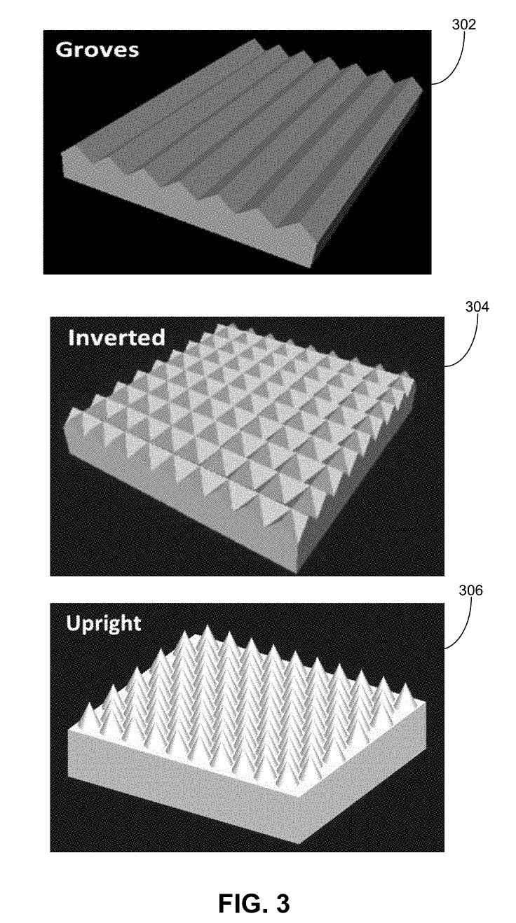

FIG. 3 shows various examples of textured back surface 218 of textured substrate 202 in PV module 200 in accordance with one embodiment described herein. For example, textured structure 302 can include a directional array of grooves. Textured structure 304 can include an array of inverted square pyramids. More specifically, each feature within textured structure 304 can be a “pit” or “hole” formed inside the glass substrate having the shape of a square pyramid. Although not shown, another textured structure on the back surface of the textured substrate 202 can be implemented as an array of upright square pyramids which can be the inverse of textured structure 304. Lastly in FIG. 3, textured structure 306 can include an array of upright cones. In some embodiments, the features of the textured substrate can be distributed based on a certain repeating pattern, such as square lattice, rectangular lattice, centered rectangular lattice, among others. In other embodiments, the features of the textured substrate can be distributed randomly across the back surface of the substrate.

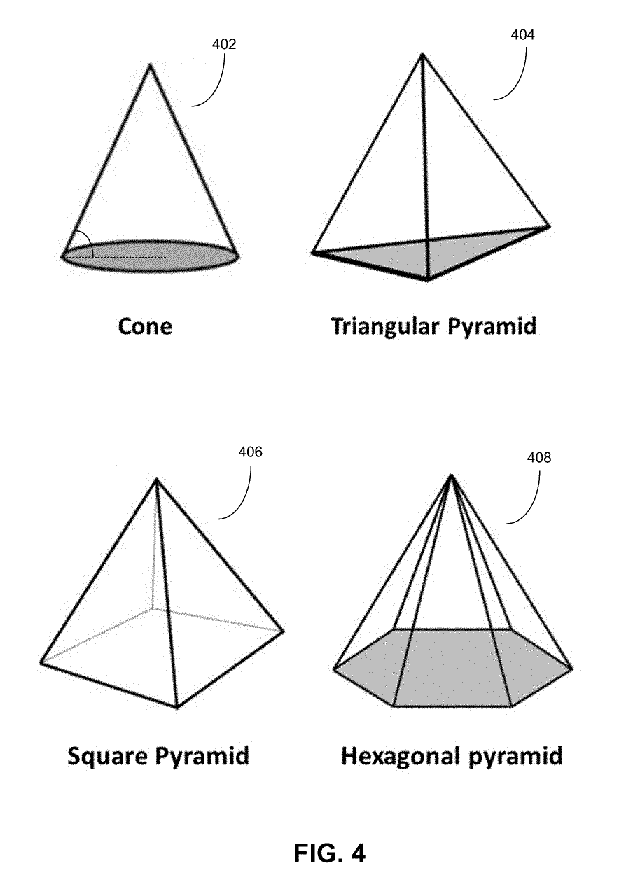

FIG. 4 shows various examples of the 3D feature shapes which can be used to form the textured back surface 218 of the textured substrate 202 in PV module 200 in accordance with one embodiment described herein. For example, these shapes can include, but are not limited to, cone 402, triangular pyramid 404, square pyramid 406, and hexagonal pyramid 408. The textured back surface 218 of substrate 202 can be configured based on any of these shapes in both upright configurations and inverted configurations. In some embodiments, the top of these features forming the textured structure can be flat with a smooth transition instead of having a sharp angle as illustrated in FIGS. 3 and 4 and some other exemplary designs illustrated below.

One important design parameter associated with the various exemplary 3D feature shapes above is the angle formed between a sidewall of a feature and the base of that feature. For example, in cone shape 402 in FIG. 4, this angle is greater than 45°. In the groove structure shown in FIG. 3, this angle is less than 45°. We refer to this angle within a given feature as a “texture angle” in the discussion below. Although the various examples illustrated in FIGS. 3-4 show the texture angles of the features as a constant, other embodiments of the textured structure can be formed with features having variable angles, for example, by using sloped sidewalls in the features instead of straight sidewalls shown in FIGS. 3 and 4.

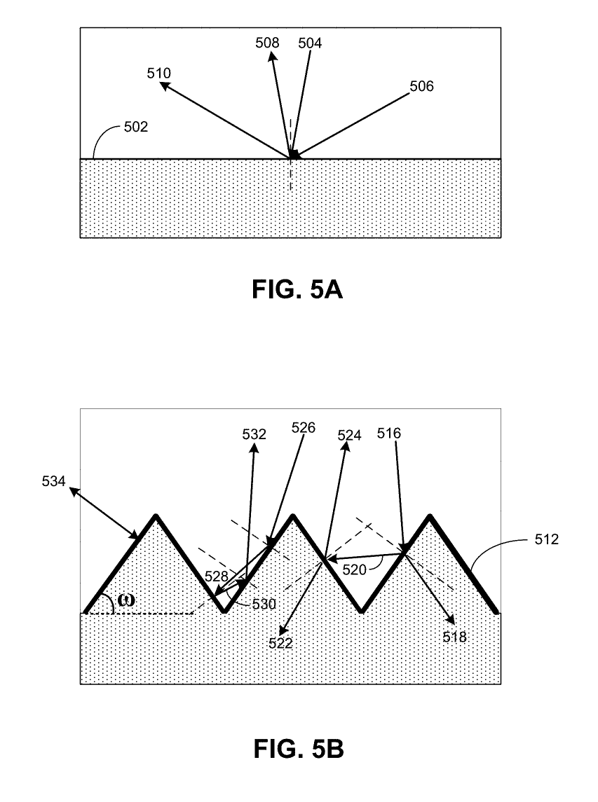

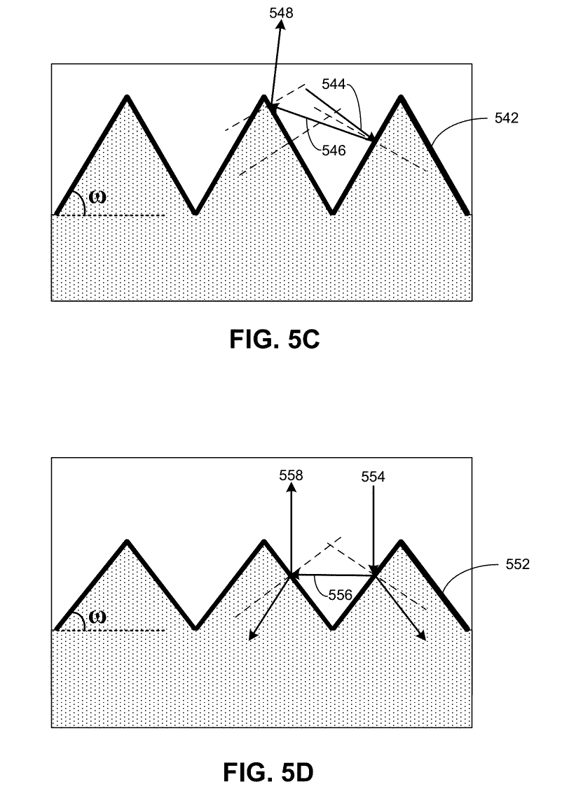

An improvement of using textured substrate 202 over flat substrate 102 in a PV module is to significantly reduce reflection loss introduced by embedding the color filter within the PV module. FIGS. 5A-5D illustrate how using a textured substrate can reduce the reflection loss at an interface between the substrate and the color filter. More specifically, FIG. 5A presents a diagram illustrating a cross-sectional view of an exemplary flat interface 502 formed between a flat back surface of a transparent substrate and a flat color filter, such as the one in PV module 100 in accordance with one embodiment described herein. As can be seen in FIG. 5A, each incident light beam, such as a light beam 504 striking interface 502 nearly vertically (i.e., a small incident angle), and a light beam 506 incident upon interface 502 at a large angle, are both at least partially reflected into reflected beams 508 and 510, respectively. In some scenarios, an incident light beam can be completely reflected off of interface 502 as a result of totally internal reflection.

FIG. 5B presents a diagram illustrating a cross-sectional view of an exemplary textured interface 512 formed between a textured back surface of a transparent substrate and a color filter deposited on the textured transparent substrate, such as the one in PV module 200 in accordance with one embodiment described herein. As can be seen in FIG. 5B, textured interface 512 has a sidewall slope which can be characterized by a texture angle ω, wherein a larger texture angle ω corresponds to a steeper sidewall slope whereas a smaller texture angle ω corresponds to a shallower sidewall slope (note that a zero texture angle ω reduces the textured interface to a flat surface as in FIG. 5A).

FIG. 5B shows a number of exemplary incident light beams at various incident angles. Note that the incident angle of an exemplary incident light beam is described below with respect to a normal direction perpendicular to the top surface of the textured substrate which is assumed to be flat. For example, an incident beam 516 strikes textured interface 512 at near a vertical angle (i.e., a small incident angle). Incident beam 516 is then partially refracted (beam 518) and partially reflected (beam 520). Instead of returning directly back to the air like light beams 504 and 506 in FIG. 5A, reflected beam 520 strikes another part of textured interface 512, and gets partially refracted (beam 522) and partially reflected (beam 524) for the second time, at which point reflected beam 524 travels upward away from textured interface 512. Comparing to beam 504 in FIG. 5A, incident light beam 516 bounces off textured interface 512 twice, and each time gets partially refracted. The overall effect of textured interface 512 on incident light beam 516 is that it causes more refraction and thereby less power in the final reflected light beam 524 compared to the single reflected beams 508 and 510 shown in FIG. 5A.

Also shown in FIG. 5B is another incident light beam 526 which strikes textured interface 512 at a greater incident angle than incident beam 516 does. Incident beam 526 is then partially refracted (not shown) and partially reflected (beam 528). Reflected beam 528 strikes another part of textured interface 512, and gets partially refracted (not shown) and partially reflected (beam 530) for the second time. Reflected beam 530 is bounced back to the same portion of textured interface 512 near where incident light beam 526 initially strikes, and gets partially refracted (not shown) and partially reflected (beam 532) for the third time and at which point, reflected beam 532 travels upward away from textured interface 512. Comparing to light beams 504 and 506 in FIG. 5A, incident beam 526 bounces off textured interface 512 three times, and each time gets partially refracted. The overall effect of textured interface 512 on incident light beam 526 is that it causes even more refraction and therefore even less power in the final reflected light beam 532 compared to the single reflected beams 508 and 510 shown in FIG. 5A.

FIG. 5B also shows a “single bounce” incident light beam 534 which strikes textured interface 512 at a large incident angle (e.g., near the texture angle ω) which is then partially refracted and partially reflected away from textured interface 512. However, when an incident light beam initially strikes textured interface 512 between a range of incident angles, for example, in some cases, between zero degree and the texture angle ω, that incident light beam is most likely to experience multiple refractions and reflections on textured interface 512, thereby leading to a significantly reduced final reflected power back into the air. Moreover, when the corresponding PV module, such as PV module 200 is properly oriented toward the light source, the large incident angle light beams outside of the range of incident angles which induces multiple reflections, may only count for a small percentage of the overall incident light. Consequently, the majority of the incident light beams will make multiple bounces/reflections on textured interface 512, thereby further reducing the overall reflection loss.

In some embodiments, the reduction of reflection losses can be controlled by the design parameters of the textured substrate, which includes controlling the texture angle ω. FIG. 5C illustrates the effect of using a greater texture angle ω within an exemplary textured interface 542 on the reduction of reflection losses in accordance with one embodiment described herein. As can be seen in FIG. 5C, textured interface 542 has a steeper sidewall slope than the sidewall slope in textured interface 512 in FIG. 5B due to a greater texture angle ω in FIG. 5C. Also shown in FIG. 5C is an incident light beam 544 which has the same incident angle as incident beam 534 shown in FIG. 5B. However, different from incident light beam 534 which is reflected on textured interface 512 only once, incident beam 544 gets partially refracted (not shown) and partially reflected (beam 546) at textured interface 542 for the first time, and reflected beam 546 gets partially refracted (not shown) and partially reflected (beam 548) at another part of textured interface 542 for the second time. Consequently, comparing to light beam 534 in FIG. 5B, incident light beam 544 which has the same incident angle as light beam 534, bounces off textured interface 542 twice, thereby experiences less reflection loss compared to the single bounce beam 534 in FIG. 5B.

The example of FIG. 5C shows that, by increasing the texture angle ω, the range of incident angles for the incident light to experience multiple refractions and multiple reflections on the textured interface has also been increased, thereby leading to even more reduction in reflection loss when compared to the exemplary textured interface 512 shown in FIG. 5B.

In some embodiments, when the corresponding PV module, such as PV module 200 is properly oriented relative to the light source, majority of the incident light beams strike the PV module in the normal direction perpendicular to the top surface of the textured substrate, such as textured substrate 202. Hence, when the textured substrate in a given PV module is configured to force the majority of the incident light beams to make multiple reflections and refractions, the overall reflection loss at the textured interface as a result of embedding a color filter structure can be greatly reduced. In some embodiments, there exists a value for the texture angle ω which would force majority of the incident light beams to experience multiple reflections and refractions. We refer to this angle as the “critical angle.”

FIG. 5D presents a diagram illustrating a cross-sectional view of an exemplary textured interface 552 formed between a textured back surface of a transparent substrate and a color filter in a PV module and having a texture angle set at a value to cause majority of the incident light to experience multiple reflections in accordance with one embodiment described herein. As can be seen in FIG. 5D, an incident light beam 554 strikes the PV module in the normal direction perpendicular to the top surface of the texture substrate. In some embodiments, incident light beam 554 represents the majority of the incident light when the PV module has been properly oriented relative to the light source. Incident light beam 554 is then partially refracted (not shown) and partially reflected (beam 556) and travels to the left.

As can be observed in FIG. 5D, if reflected light beam 556 travels substantially horizontally as shown, light beam 556 is guaranteed to strike another part of textured interface 552 to generate a second reflection (i.e., beam 558) and refraction (not shown). This condition yields a texture angle ω ˜45° by a simple geometry analysis. It can be further observed that, if the texture angle ω is set to be greater than 45°, light beam 556 will travel in a further downward angle, which also guarantees a second reflection. However, if the texture angle ω is set to be less than 45°, light beam 556 will travel in a more upward angle, which may or may not strike textured interface 552 again to generate a second reflection and refraction. Hence, in the embodiment of FIG. 5D, the critical angle is about 45°. However, in other embodiments, due to the complexity of the textured structure, the critical angle can be greater or smaller than 45°. In some embodiments, for each design of the textured substrate in the disclosed PV module, the critical angle can be first determined, for example, by simulation and/or experiment, and the texture angle ω of the textured structure is set to be substantially equal to or greater than the determined critical angle (e.g., 45°). As a result, the majority of reflections back into the air from the textured interface would come from multiple reflections. When majority of the reflections are the result of multiple reflections, the disclosed PV modules having textured substrates can reduce the reflection loss due to the embedded color filter to below 15%. At the same time, the color appearance achieved by the embedded color filter is maintained due to the wavelength-selective nature in each resulting reflection at the textured interface between the textured back surface of the transparent substrate and the top surface of the color filter.

In various embodiments, the color filter in a disclosed PV module, such as color filter 212 in PV module 200 includes a multilayer stack formed by a combination of high refraction index (e.g., n=1.7-2.5) material, such as TiO₂, Ta₂O₅, NbO₂, ZnO, SnO₂, In₂O₃, Si₃N₄, and aluminum-doped zinc oxide (AZO), low refraction index (e.g., n=1.2-1.5) material, such as SiO₂, MgF₂, and metal, such as Ag, Cu, and Au. A multilayer color filter allows for more control options to achieve the desired wavelength-selective reflections. For mass production of such color filters, the multiple optical coatings can be directly deposited on the textured surface of the transparent substrate by one of the high precision deposition techniques, such as, CVD, PVD, or sputtering. In some embodiments, to make mass production feasible, the depositions of the multilayer structure to form the color filter are performed at the PV module levels after solar cell modules have been assembled into PV modules, instead of at the solar cell levels.

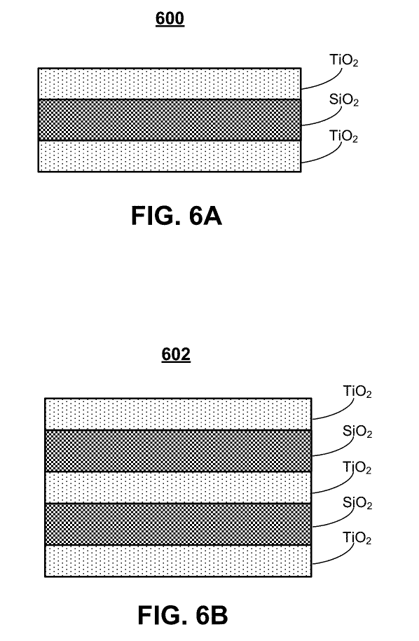

FIG. 6A presents a diagram illustrating a cross-sectional view of an exemplary structure 600 for color filter 212 in PV module 200 in accordance with one embodiment described herein. As can be seen in FIG. 6A, structure 600 is a three-layer stack of TiO₂/SiO₂/TiO₂. To achieve a desired color appearance, the three-layer stack needs to provide sufficient selectivity of the target wavelength. In one embodiment, the three-layer stack has thickness values of 75 nm/122 nm/75 nm to achieve a red appearance (i.e., selective reflections at red wavelengths). FIG. 6B presents a diagram illustrating a cross-sectional view of another exemplary structure 602 for color filter 212 described in FIG. 2 in accordance with one embodiment described herein. As can be seen in FIG. 6B, structure 602 can be a five-layer stack of TiO₂/SiO₂/TiO₂/SiO₂/TiO₂.

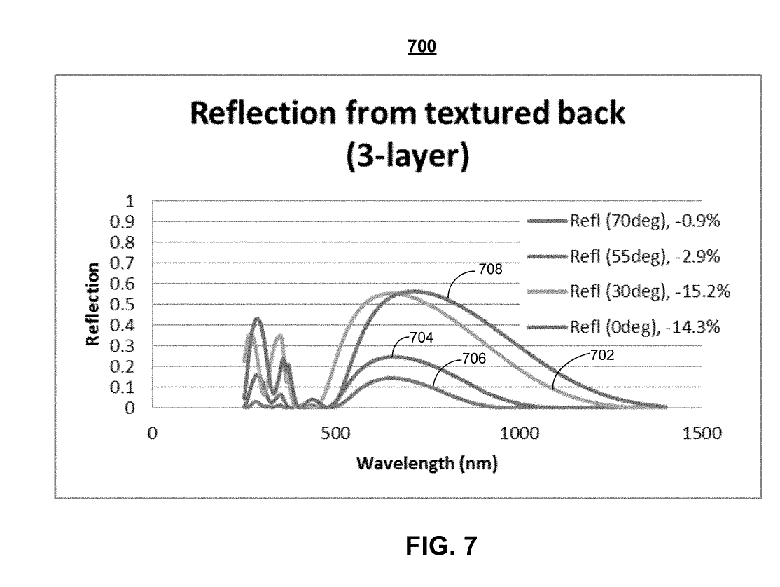

FIG. 7 presents plot 700 showing simulated reflection spectra of different designs of the textured glass substrate in combination with a three-layer color filter in exemplary PV modules in accordance with one embodiment described herein. The horizontal axis of plot 700 represents the wavelength while the vertical axis of plot 700 represents the reflectance at the textured interface between the textured back surface of the glass substrate and the top surface of the color filter. The three reflection spectra 702, 704, and 706 correspond to three texture angles of 30°, 55°, and 70°, of the texture interface, respectively. Note that plot 700 also includes a reflection spectrum 708 for a flat glass substrate as the reference for the other spectra.

As can be seen in FIG. 7, all textured substrate designs show high reflections in the 550 nm-780 nm wavelength region and low reflections in the 380 nm-550 nm wavelength region to achieve the red PV module appearance. However, for the flat glass surface (curve 708) and shallow-angled textured glass substrate (curve 702), the optical coatings in the corresponding color filter generate a strong reflection (e.g., over 50% in both cases) in red wavelength region, which causes a significant amount of reflection and current losses to corresponding PV modules. In contrast, the designs of the textured glass substrates with steeper texture angles (i.e., curves 704 and 706) can significantly lower the reflection intensity (e.g., below 20% in the case of 70° texture angle) in the same wavelength region. As discussed above, this reduction of reflection loss is achieved by causing multiple reflections for the majority of the incident light. However, the red color appearance for the large texture angle designs is still maintained by the same wavelength-selective characteristics of the three-layer color filter used within these designs. This is evidential in plot 700 because the profiles of the steep texture angle designs mimic the profiles of the shallow texture angle and flat surface designs.

In some embodiments, by further improving the designs of the textured structure of the substrate and the multilayer structure of the color filter, the reflection loss at the red wavelength region can be reduced to 10% or less. The results shown in FIG. 7 demonstrate the effectiveness of reducing the reflection loss while maintaining desired color appearance by controlling the shape of the textured structure, such as the texture angle as a design parameter. It also shows that, to achieve both low current loss and desired color appearance in the colored PV modules, large textured angles ω in the textured structure of the substrate may be preferred. In some embodiments, the color selectivity of the colored PV modules can be further improved by using a color filter structure with more than three layers. For example, by using a 5-layer stack of alternating TiO₂/SiO₂ shown in FIG. 6B, the reflection spectra in the red wavelength region show a narrower profile than the corresponding reflection spectra for the 3-layer stack structure shown in FIG. 7, indicating a stronger wavelength selectivity. Hence, by using more layers in the color filter structure, the actual color appearance can become more accurate.

One of the drawbacks associated with conventional colored PV modules is that the resulting color appearance is highly angle-sensitive. Typically, when the viewing angle increases, the color appearances shift toward shorter wavelengths (i.e., toward bluer wavelengths); and when viewing angle decreases, the color appearances shift toward longer wavelengths (i.e., towards redder wavelengths). This effect is largely the result of that a larger viewing angle receives reflections of light having larger incident angles while a smaller viewing angle receives reflections of light having smaller incident angles.

However, using the disclosed colored PV modules composed of multilayer color filters formed on the textured back surfaces of the transparent substrates, the angle sensitivity of the resulting color appearances can be significantly reduced. This reduction of angle sensitivity is at least partly due to the fact that majority of the incident light experiences multiple reflections at the textured interface (when the texture angle is properly selected). As such, at a given viewing angle (when measured from a normal direction), the received reflections at that angle is no longer primarily coming from the light having incident angles at or near the viewing angle. Instead, the received reflections are a combination of reflected light corresponding to incident light at different incident angles. Hence, the disclosed colored PV modules generate desired color appearances which are not angle-sensitive.

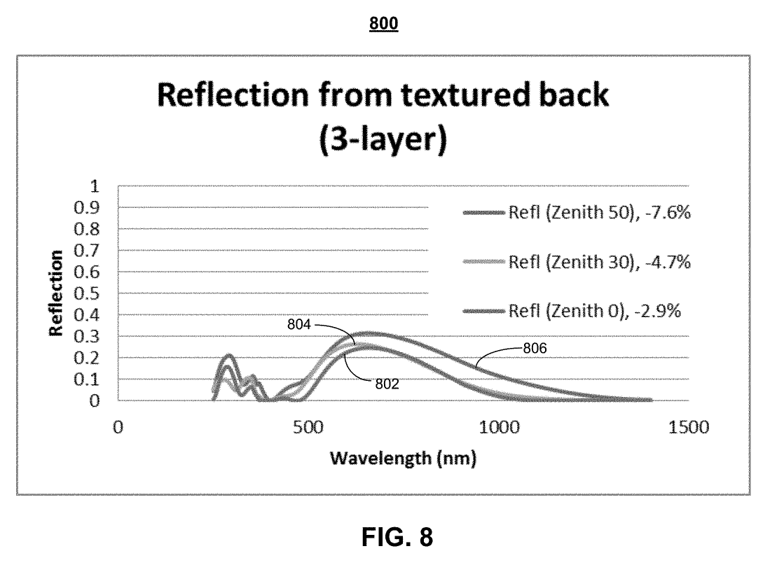

FIG. 8 presents plot 800 showing simulated reflection spectra of a three-layer color filter deposited on a 55° textured glass substrate when measured at different viewing angles in accordance with one embodiment described herein. Specifically, the three reflection spectra 802, 804, and 806 correspond to three different viewing angles (i.e., the zenith angles in plot 800) at 0, 30°, and 50°, respectively. All three spectra show high reflections in the 550 nm-780 nm wavelength region and low reflections in the 380 nm-550 nm wavelength region to achieve the red PV module appearance. As can be clearly observed in FIG. 8, with the viewing angle changed from 0° to 50°, the reflection peak has merely shifted by ˜50 nm. Hence, the color appearance, which is characterized by the spectrum profile, also has little changed, indicating a low sensitive to the viewing angle. Moreover, as the viewing angle changed from 0° to 50°, the reflection loss is increased by less than 5% abs. value, indicating a smaller variation in the reflection intensity. The combined result of a small change in spectrum profile and a small change in reflection intensity demonstrates that the disclosed textured color filter structures can achieve the desired color appearance while substantially eliminating the color variation at different viewing angles (i.e., achieving a low angle-sensitivity).

We have shown above that, by increasing the texture angle of the textured structure, the reflection loss of the disclosed textured color filter can be reduced as a result of the increased multiple reflections of the incident light. Because the low angle-sensitivity of the disclosed textured color filter can also be achieved by increasing multiple reflections, it may be possible to determine a minimum texture angle which corresponds to a maximum amount of allowed color variation. However, when the texture angle is above this minimum texture angle, the color appearance can be considered not sensitive to the viewing angle. In one embodiment, this minimum texture angle is ˜22°.

The foregoing descriptions of various embodiments have been presented only for purposes of illustration and description. They are not intended to be exhaustive or to limit the present invention to the forms disclosed. Accordingly, many modifications and variations will be apparent to practitioners skilled in the art. Additionally, the above disclosure is not intended to limit the present invention.

What is claimed is:

1. A colored photovoltaic (PV) module, comprising:
a transparent substrate;
an array of solar cells encapsulated between a top encapsulation sheet and a bottom encapsulation sheet; and
a color filter structure embedded between the top encapsulation sheet and the transparent substrate and configured to cause wavelength-selective reflections of incident light received by the colored PV module;
wherein the transparent substrate includes a front surface configured to receive the incident light and a textured back surface which is configured with an array of features, wherein the color filter structure is formed on the textured back surface of the transparent substrate to create a textured interface between the textured back surface and the color filter structure.

2. The colored PV module of claim 1, wherein the textured back surface is configured to cause majority of the incident light received by the PV module to reflect at least twice on the textured interface so that the wavelength-selective reflections comprise primarily light reflected two or more times on the textured interface.

3. The colored PV module of claim 2, wherein the textured back surface is configured to control an amount of reflection loss caused by the textured interface by increasing or decreasing an amount of multiple reflections of the incident light on the textured interface, wherein increasing the amount of multiple reflections decreases the amount of reflection loss.

4. The colored PV module of claim 2, wherein the color filter structure facilitates a desired color appearance of the PV module when viewed above the front surface of the transparent substrate.

5. The colored PV module of claim 1, wherein each of the features in the textured back surface includes at least one angled sidewall, which forms a texture angle of the textured back surface with the plane of the front surface of the transparent substrate.

6. The colored PV module of claim 5, wherein the texture angle of the textured back surface is configured to cause majority of the incident light received by the PV module to reflect at least twice on the textured interface.

7. The colored PV module of claim 5, wherein the texture angle of the textured back surface is configured to control an amount of reflection loss caused by the textured interface.

8. The colored PV module of claim 7, wherein the texture angle of the textured back surface is set to be substantially equal to or greater than a threshold angle which causes majority of the incident light received by the PV module to reflect at least twice on the textured interface so that the wavelength-selective reflections from the textured interface comprise primarily light reflected two or more times on the textured interface.

9. The colored PV module of claim 8, wherein the threshold angle is approximately 45°.

10. The colored PV module of claim 1, wherein the array of features includes one of: an array of grooves, an array of cones, an array of triangular pyramids, an array of square pyramids, and an array of hexagonal pyramids.

11. The colored PV module of claim 1, wherein each of the features has both a flat top surface and a tapered sidewall.

12. The colored PV module of claim 1, wherein each of the features has a feature size ranging from 10 μm to 5 mm.

13. The colored PV module of claim 1, wherein the color filter structure comprises multiple layers of optical coatings, and wherein the multiple layers of optical coatings include alternating high refraction index and low refraction index optical coatings.

14. The colored PV module of claim 1, further comprising an antireflective coating (ARC) deposited on the front surface of the transparent substrate and configured to reduce unwanted reflections.

15. The colored PV module of claim 1, wherein the transparent substrate is a glass substrate.

16. A top glass structure for a colored photovoltaic (PV) module, comprising:
a transparent substrate which includes:
a flat front surface configured to receive incident light; and
a textured back surface configured with an array of features; and
a color filter structure formed on the textured back surface of the transparent substrate to create a textured interface between the textured back surface and the color filter structure, wherein the color filter structure is configured to cause wavelength-selective reflections of the incident light.

17. The top glass structure of claim 16, wherein the textured back surface is configured to cause majority of the incident light to reflect at least twice on the textured interface so that the wavelength-selective reflections comprise primarily light reflected two or more times on the textured interface.

18. The top glass structure of claim 16, wherein each of the features in the textured back surface includes at least one angled sidewall which forms a texture angle of the textured back surface with the plane of the front surface of the transparent substrate, and wherein the texture angle of the textured back surface is configured to cause majority of the incident light to reflect at least twice on the textured interface.

19. A method for fabricating a colored photovoltaic (PV) module, the method comprising:
preparing a transparent substrate which includes:
a flat front surface configured to receive incident light; and
a textured back surface configured with an array of features; and
forming a color filter structure on the textured back surface of the transparent substrate to create a textured interface between the textured back surface and the color filter structure, wherein the color filter structure is configured to cause wavelength-selective reflections of the incident light; and
assembling the transparent substrate and the color filter structure with an array of solar cells encapsulated between a top encapsulation sheet and a bottom encapsulation sheet.

20. The method of claim 19, wherein preparing the textured back surface of the transparent substrate includes using a texture roller process and/or one or more chemical etching processes following by a tempering process.
